(19) United States
(12) Patent Application Publication
(10) Pub. No.: US 2016/0005813 A1
(43) Pub. Date: Jan. 7, 2016

(54) FIN STRUCTURES AND METHODS OF MANFACTURING THE FIN STRUCTURES, AND FIN TRANSISTORS HAVING THE FIN STRUCTURES AND METHODS OF MANUFACTURING THE FIN TRANSISTORS

(71) Applicant: Sang-su KIM, Yongin-si (KR)

(72) Inventor: Sang-su KIM, Yongin-si (KR)

(21) Appl. No.: 14/789,367

(22) Filed: Jul. 1, 2015

(30) Foreign Application Priority Data
Jul. 2, 2014 (KR) 10-2014-0082529

(51) Int. Cl. H01L 29/06; H01L 29/16; H01L 29/78

(52) U.S. Cl. CPC H01L 29/0649; H01L 29/785; H01L 29/16

(57) ABSTRACT

Fin structures and methods of forming the fin structure are provided. Fin structures may include a semiconductor fin that is on a silicon layer and includes a Group IV semiconductor material that includes germanium, an isolation insulation layer at two lower sides of the semiconductor fin and a bottom insulation layer under the semiconductor fin and the isolation insulation layer. The silicon layer may be a bulk silicon substrate, and the semiconductor fin may be a silicon germanium (SiGe) layer, a silicon germanium carbon (SiGeC) layer, or a single germanium (Ge) layer. The bottom insulation layer may be an oxide of a Group IV semiconductor material that includes germanium, which the semiconductor fin includes.

### CROSS-REFERENCE TO RELATED APPLICATION

This U.S. non-provisional application claims priority under 35 U.S.C. §119 to Korean Patent Application No. 10-2014-0082529, filed on Jul. 2, 2014 in the Korean Intellectual Property Office, the disclosure of which is incorporated herein in its entirety by reference.

### BACKGROUND

The present inventive concepts relate to fin structures and methods of manufacturing the fin structures, and transistors including the fin structures and methods of manufacturing the transistors.

Semiconductor devices may include semiconductor fins. For example, semiconductor fins may be used as a channel area or a source/drain area to improve control characteristics according to reduction of transistor size. Semiconductor fins may need be electrically insulated from other elements.

### SUMMARY

A fin structure may include a semiconductor fin that is on a silicon layer and includes a Group IV semiconductor material that includes germanium and a bottom insulation layer under the semiconductor fin. The bottom insulation layer may include a planar portion on the silicon layer and a protruding portion protruding from the planar portion that is under the semiconductor fin. The fin structure may also include an isolation insulation layer on opposing sides of the protruding portion of the bottom insulation layer.

According to various embodiments, the silicon layer may include a bulk silicon substrate.

In various embodiments, the semiconductor fin may include a silicon germanium (SiGe) layer, a silicon germanium carbon (SiGeC) layer, or a germanium (Ge) layer.

In various embodiments, the bottom insulation layer may include an oxide of the Group IV semiconductor material that includes germanium.

According to various embodiments, the isolation insulation layer may be on opposing sides of the semiconductor fin.

According to various embodiments, the isolation insulation layer may expose opposing sides of the semiconductor fin.

According to various embodiments, an upper surface of the isolation insulation layer may be higher or lower than a lower surface of the semiconductor fin relative to an upper surface of the silicon layer.

In various embodiments, the bottom insulation layer and the isolation insulation layer may include different materials.

In various embodiments, a density of the bottom insulation layer may be higher than a density of the isolation insulation layer.

According to various embodiments, the bottom insulation layer may include a silicon germanium oxide (Si₁₋ₓGeₓO) layer, the semiconductor fin may include a silicon germanium (Si_{1-y}Ge_{y}) layer, and 0<x≦1, 0<y≦1, and x=y.

According to various embodiments, the bottom insulation layer may include a silicon germanium oxide (Si₁₋ₓGeₓO) layer, and the semiconductor fin may include a silicon germanium (Si_{1-y}Ge_{y}) layer, and 0<x≦1, 0<y≦1, and x≠y.

According to various embodiments, the bottom insulation layer may include a silicon germanium oxide (Si₁₋ₓGeₓO) layer, and the semiconductor fin may include a silicon germanium (Si_{1-y}Ge_{y}) layer, and 0.1≦x≦0.7, 0.4≦y≦1.0, and x<y.

A method of manufacturing a fin structure may include forming a first semiconductor layer on a silicon layer and forming a second semiconductor layer on the first semiconductor layer. The first and second semiconductor layers may include a Group IV semiconductor material that includes germanium. The method may also include forming a semiconductor fin by patterning the second semiconductor layer, forming an isolation insulation layer on or below opposing sides of a lower portion the semiconductor fin and forming a bottom insulation layer under the isolation insulation layer by oxidizing the first semiconductor layer while the semiconductor fin may be being protected.

According to various embodiments, the silicon layer may include a bulk silicon substrate, and each of the first semiconductor layer and the second semiconductor layer may include a silicon germanium (SiGe) layer, a silicon germanium carbon (SiGeC) layer, or a germanium (Ge) layer.

According to various embodiments, the first semiconductor layer may include a silicon germanium (Si₁₋ₓGeₓ) layer, and the second semiconductor layer may include a silicon germanium (Si_{1-y}Ge_{y}) layer, and 0<x≦1, 0<y≦1, and x=y.

According to various embodiments, the first semiconductor layer may include a silicon germanium (Si₁₋ₓGeₓ) layer, and the second semiconductor layer may include a silicon germanium (Si_{1-y}Ge_{y}) layer, and 0<x≦1, 0<y≦1, and x≠y.

In various embodiments, a lattice constant of the silicon layer may be a, a lattice constant of the first semiconductor layer may be b, and a lattice constant of the second semiconductor layer may be c, and a<b<c and 0<(c−a)/a≦0.08.

In various embodiments, the first semiconductor layer may include a silicon germanium (Si₁₋ₓGeₓ) layer, and the second semiconductor layer may include a silicon germanium (Si_{1-y}Ge_{y}) layer, and 0.1≦x≦0.7, 0.4≦y≦1.0, and x<y.

According to various embodiments, forming the semiconductor fin and the bottom insulation layer may include forming a mask layer on the second semiconductor layer, forming the semiconductor fin by etching the second semiconductor layer using the mask layer as an etching mask, forming sidewall spacers on the semiconductor fin, forming the bottom insulation layer under the isolation insulation layer by oxidizing the first semiconductor layer while the sidewall spacers remain on the semiconductor fin and removing the mask layer and the sidewall spacers.

In various embodiments, etching the second semiconductor layer may include partially etching the first semiconductor layer to form a planar pattern on the silicon layer and a protruding pattern protruding from the planar pattern that is under the semiconductor fin.

In various embodiments, the isolation insulation layer may be formed on the planar pattern.

According to various embodiments, forming the semiconductor fin and the bottom insulation layer may include forming a mask layer on the second semiconductor layer, forming the semiconductor fin by etching the second semiconductor layer using the mask layer as an etching mask, forming sidewall spacers on the semiconductor fin and forming a patterned first semiconductor layer that includes a planar pattern on the silicon layer and a protruding pattern protruding from the planar pattern that is under the semiconductor fin and the sidewall spacers by partially etching the first semiconductor layer using the mask layer and the sidewall spacers as an etching mask. Forming the semiconductor fin and the bottom insulation layer may also include forming a recessed protruding pattern under the semiconductor fin by etching opposing sides of the protruding pattern, forming the bottom insulation layer under the isolation insulation layer by oxidizing the patterned first semiconductor layer that includes the recessed protruding pattern and the planar pattern and removing the mask layer and the sidewall spacers.

In various embodiments, an upper surface of the isolation insulation layer may be formed higher or lower than a lower surface of the semiconductor fin relative to an upper surface of the silicon layer.

In various embodiments, forming the semiconductor fin by patterning the second semiconductor layer may include forming a plurality of semiconductor fins that protrude from the silicon layer in an upward direction, are spaced apart from one another in a first direction and extend in a second direction that is substantially perpendicular to the first direction. Forming the isolation insulation layer may include forming the isolation insulation layer at opposing sides of lower portions of the plurality of semiconductor fins. Oxidizing the first semiconductor layer may be performed while the plurality of semiconductor fins are being protected. The method further may include forming a gate structure that crosses the plurality of semiconductor fins and extends in the first direction and forming a source area and a drain area in each of the plurality of semiconductor fins in both sides of the gate structure.

According to various embodiments, the silicon layer may include a bulk silicon substrate, and each of the first semiconductor layer and the second semiconductor layer may include a silicon germanium (SiGe) layer, a silicon germanium carbon (SiGeC) layer, or a germanium (Ge) layer.

According to various embodiments, forming the plurality of semiconductor fins and the bottom insulation layer may include forming a mask layer on the second semiconductor layer, forming the plurality of semiconductor fins by etching the second semiconductor layer using the mask layer as an etching mask, forming sidewall spacers on opposing sides of each of the plurality of semiconductor fins prior to oxidizing the first semiconductor layer and removing the mask layer and the sidewall spacers after forming the bottom insulation layer.

According to various embodiments, etching the second semiconductor layer may include partially etching the first semiconductor layer to form a planar pattern on the silicon layer and to form protruding patterns protruding from the planar pattern under the plurality of semiconductor fins, and the isolation insulation layer may be formed on the planar pattern.

In various embodiments, forming the plurality of semiconductor fins and the bottom insulation layer may include forming a mask layer on the second semiconductor layer, forming the plurality of semiconductor fins by etching the second semiconductor layer using the mask layer as an etching mask, forming sidewall spacers on opposing sides of each of the plurality of semiconductor fins, forming a patterned first semiconductor layer that includes a planar pattern on the silicon layer and protruding patterns protruding from the planar pattern that may be under the semiconductor fins and the sidewall spacers, by partially etching the first semiconductor layer using the mask layer and the sidewall spacers as an etching mask, forming recessed protruding patterns under respective ones of the plurality of semiconductor fins by etching opposing sides of each of the protruding patterns, forming the bottom insulation layer under the isolation insulation layer by oxidizing the patterned first semiconductor layer that includes the recessed protruding patterns and the planar pattern and removing the mask layer and the sidewall spacers.

A fin transistor may include a semiconductor fin on a silicon layer, a gate structure on the semiconductor fin and an insulation structure under the gate structure and the semiconductor fin.

The semiconductor fin may include source and drain areas and may include a Group IV semiconductor material that includes germanium. The insulation structure may include an isolation insulation layer that may be disposed on opposing sides of a lower portion of the semiconductor fin and a bottom insulation layer that may be disposed under the semiconductor fin and the isolation insulation layer.

According to various embodiments, the silicon layer may include a bulk silicon substrate, and the insulation structure may be on the bulk silicon substrate, and the bottom insulation layer may include an oxide of the Group IV semiconductor material.

According to various embodiments, the bottom insulation layer may include a planar portion on the silicon layer and a protruding portion protruding from the planar portion that is under the semiconductor fin, and the isolation insulation layer may be on opposing sides of the protruding portion of the bottom insulation layer.

According to various embodiments, the bottom insulation layer and the isolation insulation layer may include different materials, and a density of the bottom insulation layer may be higher than a density of the isolation insulation layer:

In various embodiments, each of the source and drain areas may include an n-type impurity area or a p-type impurity area.

In various embodiments, a width of the semiconductor fin may vary along a direction that the gate structure extends on both sides of the gate structure.

According to various embodiments, the semiconductor fin may include a first semiconductor fin among a plurality of semiconductor fins that protrude from the silicon layer in an upward direction that is substantially perpendicular to an upper surface of the silicon layer. The plurality of semiconductor fins may be spaced apart from one another in a first direction, may extend in a second direction that is substantially perpendicular to the first direction and may include a Group IV semiconductor material that includes germanium. The gate structure may be disposed on the plurality of semiconductor fins and extends in the first direction, and the insulation structure may be disposed under the plurality of semiconductor fins. The isolation insulation layer may be on opposing sides of a lower portion of each of the plurality of semiconductor fins and between adjacent ones of the plurality of semiconductor fins, and the bottom insulation layer may be disposed under the plurality of semiconductor fins and the isolation insulation layer and on the silicon layer.

In various embodiments, the bottom insulation layer may include an oxide layer of the Group IV semiconductor material and may include a planar portion on the silicon layer and a plurality of protruding portions protruding from the planar portion under the plurality of semiconductor fins. The isolation insulation layer may be on opposing sides of each of the plurality of protruding portions of the bottom insulation layer.

In various embodiments, an upper surface of the isolation insulation layer may be higher or lower than lower surfaces of the plurality of semiconductor fins relative to an upper surface of the silicon layer.

According to various embodiments, the bottom insulation layer and the isolation insulation layer may include different materials, and a density of the bottom insulation layer may be higher than a density of the isolation insulation layer.

According to various embodiments, a width of each of the plurality of semiconductor fins may vary along the second direction on both sides of the gate structure.

In various embodiments, the plurality of semiconductor fins may be merged into a unitary semiconductor fin on both sides of the gate structure.

A method of forming a Fin-Field Effect Transistor (FET) may include forming a semiconductor fin on a substrate and forming an isolation insulation layer having first and second sidewalls that are vertically aligned with respective first and second opposing sidewalls of the semiconductor fin. The semiconductor fin may include germanium and may protrude in a vertical direction that is substantially perpendicular to an upper surface of the substrate. The method may also include forming a bottom insulation layer between the semiconductor fin and the substrate. The bottom insulation layer may include germanium and may include a horizontal portion that extends along the upper surface of the substrate and a vertical portion that protrudes toward the semiconductor fin in the vertical direction and directly contacts the semiconductor fin.

According to various embodiments, the bottom insulation layer may include a silicon germanium oxide (Si₁₋ₓGeₓO) layer, and the semiconductor fin may include a silicon germanium (Si_{1-y}Ge_{y}) layer, and 0.1≦x≦0.7, 0.4≦y≦1.0, and x<y.

In various embodiments, forming the semiconductor fin and the bottom insulation layer may include forming a first semiconductor layer including germanium on the substrate, forming a second semiconductor layer including germanium on the first semiconductor layer and sequentially patterning the second semiconductor layer and the first semiconductor layer to form the semiconductor fin and a patterned first semiconductor layer, respectively. The patterned first semiconductor layer may include a horizontal portion that extends along the upper surface of the substrate and a vertical portion that protrudes toward the semiconductor fin in the vertical direction and contacts the semiconductor fin. Forming the semiconductor fin and the bottom insulation layer may also include oxidizing the patterned first semiconductor layer, after forming the isolation insulation layer, to form the bottom insulation layer.

According to various embodiments, the method may further include forming spacers on the first and second opposing sidewalls of the semiconductor fin and on the isolation insulation layer prior to oxidizing the patterned first semiconductor layer.

According to various embodiments, a lattice constant of the substrate may be a, a lattice constant of the first semiconductor layer may be b, and a lattice constant of the second semiconductor layer may be c, and a<b<c and 0<(c−a)/a≦0.08.

In various embodiments, forming the semiconductor fin and the bottom insulation layer may include forming a first semiconductor layer including germanium on the substrate, forming a second semiconductor layer including germanium on the first semiconductor layer, patterning the second semiconductor layer to form the semiconductor fin, forming spacers on the first and second opposing sidewalls of the semiconductor fin, patterning the first semiconductor layer using the spacer as an etching mask to form a patterned first semiconductor layer and oxidizing the patterned first semiconductor layer, prior to forming the isolation insulation layer, to form the bottom insulation layer.

According to various embodiments, forming the semiconductor fin may include forming a plurality of semiconductor fins on the substrate, each of the plurality of semiconductor fins including germanium and protruding in the vertical direction. The bottom insulation layer may be formed between the plurality of semiconductor fins and the substrate, the vertical portion of the bottom insulation layer may include a plurality of vertical portions that protrude toward respective ones of the plurality of semiconductor fins in the vertical direction and may directly contact the respective ones of the plurality of semiconductor fins. The method may further include forming a gate structure that crosses the plurality of semiconductor fins.

### BRIEF DESCRIPTION OF THE DRAWINGS

Some embodiments of the present inventive concepts will be more clearly understood from the following detailed description taken in conjunction with the accompanying drawings in which:

FIG. 1 is a schematic structural cross-sectional view of a fin structure according to some embodiments of the present inventive concepts;

FIGS. 2 and 3 are schematic structural cross-sectional views of a fin structure according to some embodiments of the present inventive concepts;

FIGS. 4 through 8 are schematic cross-sectional views illustrating a method of manufacturing a fin structure according to some embodiments of the present inventive concepts;

FIGS. 9 through 13 are schematic cross-sectional views illustrating a method of manufacturing a fin structure according to some embodiments of the present inventive concepts;

FIG. 14 is a schematic perspective view of a fin transistor including a single semiconductor fin according to some embodiments of the present inventive concepts;

FIG. 15 is a schematic perspective view of a fin transistor including a single semiconductor fin according to some embodiments of the present inventive concepts;

FIG. 16 is a schematic perspective view of a fin transistor including a plurality of semiconductor fins according to some embodiments of the present inventive concepts;

FIGS. 17 and 18 are schematic perspective views of a fin transistor including a plurality of semiconductor fins according to some embodiments of the present inventive concepts;

FIGS. 19 through 24 are schematic cross-sectional views illustrating a method of manufacturing a fin transistor including a plurality of semiconductor fins according to some embodiments of the present inventive concepts;

FIGS. 25 through 31 are schematic cross-sectional views illustrating a method of manufacturing a fin transistor including a plurality of semiconductor fins according to some embodiments of the present inventive concepts;

FIG. 32 is a perspective view of a fin transistor including semiconductor fins according to some embodiments of the present inventive concepts;

FIG. 33 is a perspective view of a fin transistor including semiconductor fins according to some embodiments of the present inventive concepts;

FIG. 34 is a circuit diagram of an inverter including a fin transistor according to some embodiments of the present inventive concepts;

FIG. 35 is a schematic view illustrating a card including a fin transistor according to some embodiments of the present inventive concepts;

FIG. 36 is a schematic view illustrating an electronic system including a fin transistor according to some embodiments of the present inventive concepts; and

FIG. 37 is a schematic perspective view illustrating an electronic device including a fin transistor according to some embodiments of the present inventive concepts.

### DETAILED DESCRIPTION

The present inventive concepts will now be described more fully with reference to the accompanying drawings, in which some embodiments of the present inventive concepts are shown. The present inventive concepts may, however, be embodied in many different forms, and should not be construed as being limited to the embodiments set forth herein. Rather, these embodiments are provided so that this disclosure will be thorough and complete, and will fully convey the concepts of the present inventive concepts to those skilled in the art. In the drawings, the thicknesses or sizes of layers are exaggerated for clarity.

In the present specification, when a constituent element such as a film, a layer, a region, or a substrate is “on” or “connected” or “coupled” to another constituent element, it may be construed that the constituent element is on or connected or coupled to the other constituent element not only directly but also through at least one of other constituent elements interposed therebetween. On the other hand, when a constituent element such as a film, a layer, a region, or a substrate is “directly on” or “directly connected” or “directly coupled” to another constituent element, it is construed that there is no other constituent element interposed therebetween. Like reference numerals denote like elements throughout the specification.

In the present description, terms such as ‘first’, ‘second’, etc. are used to describe various members, components, regions, layers, and/or portions. However, it is obvious that the members, components, regions, layers, and/or portions should not be defined by these terms. The terms are used only for distinguishing one member, component, region, layer, or portion from another member, component, region, layer, or portion. Thus, a first member, component, region, layer, or portion which will be described may also refer to a second member, component, region, layer, or portion, without departing from the teaching of the present inventive concepts. As used herein, the term “and/or” includes any and all combinations of one or more of the associated listed items.

In addition, relative terms such as “on” or “above”, and “under” or “below” may be used to describe relationship between elements as illustrated in the drawings. These relative terms can be understood to include different directions in addition to the described directions illustrated in the drawings. For example, when elements are turned over in the drawings, elements described to be on lower surfaces of other elements are on upper surfaces of the other elements. Therefore, the term “on” depends only on a predetermined direction and can include both “lower” and “upper” directions. If a device is directed in a different direction (for example, a direction rotated by 90 degrees with respect to another direction), the description of the relative terms will be interpreted accordingly.

The terminology used herein is for the purpose of describing particular embodiments only and is not intended to be limiting of the embodiments. As used herein, the singular forms “a,” “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the drawings, for example, according to the manufacturing techniques and/or tolerances, shapes of the illustrated elements may be modified. Thus, the present inventive concepts should not be construed as being limited to the embodiments set forth herein and should include, for example, variations in the shapes during manufacture.

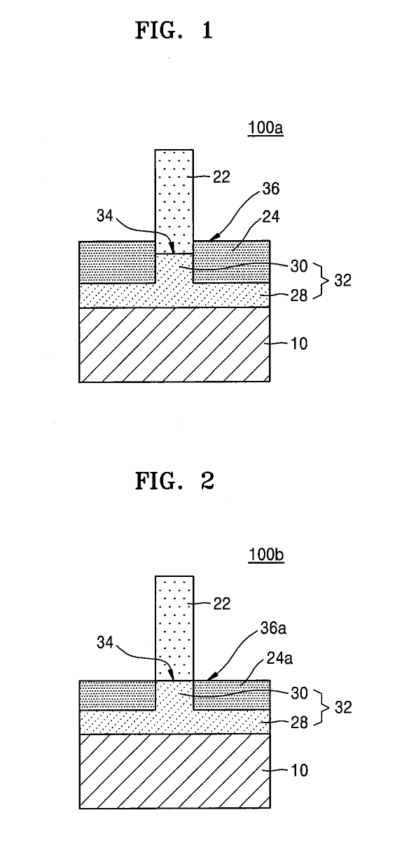

FIG. 1 is a schematic structural cross-sectional view of a fin structure 100a according to some embodiments of the present inventive concepts.

In detail, the fin structure 100a may include a semiconductor fin 22 that is formed of a Group IV semiconductor material including germanium (Ge) and is formed on a silicon layer 10. The semiconductor fin 22 may be a silicon germanium (SiGe) layer, a silicon germanium carbon (SiGeC) layer, or a germanium (Ge) layer.

Compared to silicon, germanium included in the semiconductor fin 22 has a higher carrier mobility, for example, electron mobility or hole mobility, and thus, when a transistor includes a fin that includes germanium, the transistor may operate at higher speeds. The semiconductor fin 22 may be formed on the silicon layer 10, which is, for example, a bulk silicon substrate. A bottom insulation layer 32 may be formed under the semiconductor fin 22 and an isolation insulation layer 24. The bottom insulation layer 32 may include a planar portion 28 formed on the silicon layer 10 and a protruding portion 30 protruding from a surface of the planar portion 28 to the semiconductor fin 22. It will be understood that a planar portion 28 refers to a horizontal portion of the bottom insulation layer 32.

The isolation insulation layer 24 may be formed adjacent a lower portion of the semiconductor fin 22. The isolation insulation layer 24 may be formed on opposing sidewalls of the lower portion of the semiconductor fin 22. The isolation insulation layer 24 may be formed on two sides (i.e., opposing sides) of the protruding portion 30 of the bottom insulation layer 32. An upper surface 36 of the isolation insulation layer 24 may be higher above a bottom surface of the substrate 10 than a lower surface 34 of the semiconductor fin 22. Accordingly, current leakage under the semiconductor fin 22 may be reduced.

The bottom insulation layer 32 and the isolation insulation layer 24 may be formed of different materials. The bottom insulation layer 32 may be an oxide layer formed by oxidizing a Group IV semiconductor material that includes germanium, which the semiconductor fin 22 is formed of. For example, the bottom insulation layer 32 may be a silicon germanium oxide (SiGeO) layer or a germanium oxide (GeO) layer.

The isolation insulation layer 24 may be formed by depositing an insulation material on the bottom insulation layer 32. For example, the isolation insulation layer 24 may be a silicon oxide layer. Accordingly, a density of the bottom insulation layer 32 may be higher than a density of the isolation insulation layer 24. That is, a layer compactness of the bottom insulation layer 32 may be higher than that of the isolation insulation layer 24. When a density of the bottom insulation layer 32 is higher than that of the isolation insulation layer 24, electrical insulation between the semiconductor fin 22 and the silicon layer 10 may be improved.

According to some embodiments of the present inventive concepts, the bottom insulation layer 32 may be a silicon germanium oxide (Si₁₋ₓGeₓO) layer, and the semiconductor fin 22 may be a silicon germanium (Si_{1-y}Ge_{y}) layer, where 0<x≦1 and 0<y≦1, and x=y or x≠y. In some embodiments, both x and y may be 1, the bottom insulation layer 32 may be a germanium oxide layer, and the semiconductor fin 22 may be a germanium layer.

According to some embodiments of the present inventive concepts, the bottom insulation layer 32 may be a silicon germanium oxide (Si₁₋ₓGeₓO) layer, and the semiconductor fin 22 may be a silicon germanium (Si_{1-y}Ge_{y}) layer, where 0.1≦x≦0.7, 0.4≦y≦1.0, and x<y. The values of x and y may be determined so as to improve an insulation property of the bottom insulation layer 32 and the carrier mobility of the semiconductor fin 22.

The semiconductor fin 22 that is included in the fin structure 100a may include germanium which has a high carrier mobility and may be electrically insulated from other elements (e.g., the silicon layer 10) by the isolation insulation layer 24 and the bottom insulation layer 32.

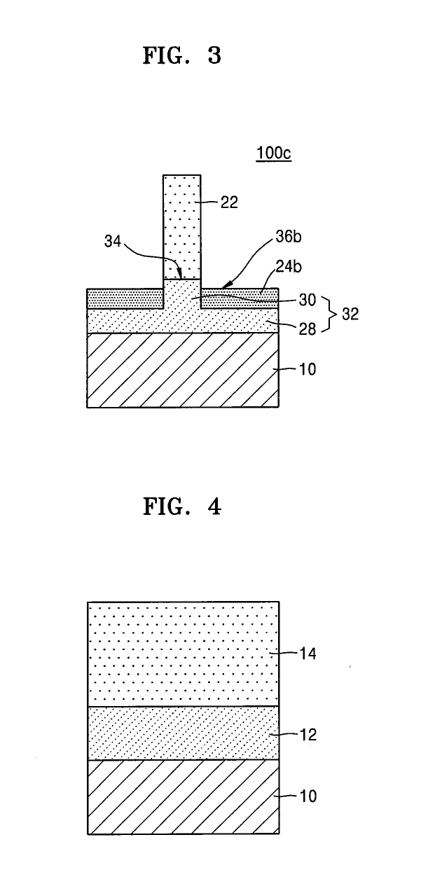

FIGS. 2 and 3 are schematic structural cross-sectional views of fin structures according to some embodiments of the present inventive concepts.

In detail, the fin structures 100b and 100c of FIGS. 2 and 3 are similar to the fin structure 100a of FIG. 1 except for isolation insulation layers 24a and 24b. In regard to the fin structures 100b and 100c of FIGS. 2 and 3, the same elements as those of the fin structure 100a of FIG. 1 will not be described.

In the fin structure 100b of FIG. 2, an upper surface 36a of an isolation insulation layer 24a may be at the same height as the lower surface 34 of the semiconductor fin 22 relative to an upper surface of the silicon layer 10. Compared to the fin structure 100a of FIG. 1, a height of the semiconductor fin 22 of the fin structure 100b of FIG. 2 may be higher.

In the fin structure 100c of FIG. 3, an upper surface 36b of the isolation insulation layer 24b may be lower than the lower surface 34 of the semiconductor fin 22. Compared to the fin structure 100a of FIG. 1, the semiconductor fin 22 of the fin structure 100c does not contact the isolation insulation layer 24b that has a lower density than a density of the bottom insulation layer 32. Accordingly, insulation between the semiconductor fin 22 and the silicon layer 10 may be further improved in the fin structure 100c of FIG. 3.

FIGS. 4 through 8 are schematic cross-sectional views illustrating a method of manufacturing a fin structure according to some embodiments of the present inventive concepts.

In detail, the method illustrated in FIGS. 4 through 8 may be used to manufacture the fin structures 100a and 100b of FIGS. 1 and 2.

Referring to FIG. 4, a first semiconductor layer 12 that comprises a Group IV semiconductor including germanium (Ge) may be formed on a silicon layer 10. The silicon layer 10 may be, for example, a bulk silicon substrate. The first semiconductor layer 12 may be formed using a Group IV material source including germanium (Ge) and using an epitaxial deposition method.

A second semiconductor layer 14 that is formed of a Group IV semiconductor material including germanium (Ge) may be formed on the first semiconductor layer 12. The second semiconductor layer 14 may be formed using a Group IV material source including germanium (Ge) and using an epitaxial deposition method. The first semiconductor layer 12 and the second semiconductor layer 14 may be a SiGe layer, a SiGeC layer, or a germanium (Ge) layer.

According to some embodiments of the present inventive concepts, the first semiconductor layer 12 may be a silicon germanium (Si₁₋ₓGeₓ) layer, and the second semiconductor layer 14 may be a silicon germanium (Si_{1-y}Ge_{y}) layer, where 0<x≦1 and 0<y≦1, and x=y or x≠y. In some embodiments, both x and/or y may be 1, so that the first semiconductor layer 12 and the second semiconductor layer 14 may be germanium layers. In some embodiments, the values of x and y may be equal, and the first semiconductor layer 12 and the second semiconductor layer 14 may be a single material layer.

According to some embodiments of the present inventive concepts, a lattice constant of the silicon layer 10 is “a”, a lattice constant of the first semiconductor layer 12 is “b”, a lattice constant of the second semiconductor layer 14 is “c”, and a<b<c and 0<(c−a)/a≦0.08.

Ranges of the lattice constants of the silicon layer 10, the first semiconductor layer 12, and the second semiconductor layer 14 may be determined so as to improve conditions for forming the first semiconductor layer 12 and the second semiconductor layer 14 and insulation characteristics and carrier mobility of a semiconductor fin that is subsequently formed.

According to some embodiments of the present inventive concepts, the first semiconductor layer 12 may be a silicon germanium (Si₁₋ₓGeₓ) layer, and the second semiconductor layer 14 may be a silicon germanium (Si_{1-y}Ge_{y}) layer, where 0.1≦x≦0.7, 0.4≦y≦1.0, and x<y. The values of x and y may be determined so as to improve insulation characteristics and carrier mobility of a semiconductor fin that is subsequently formed.

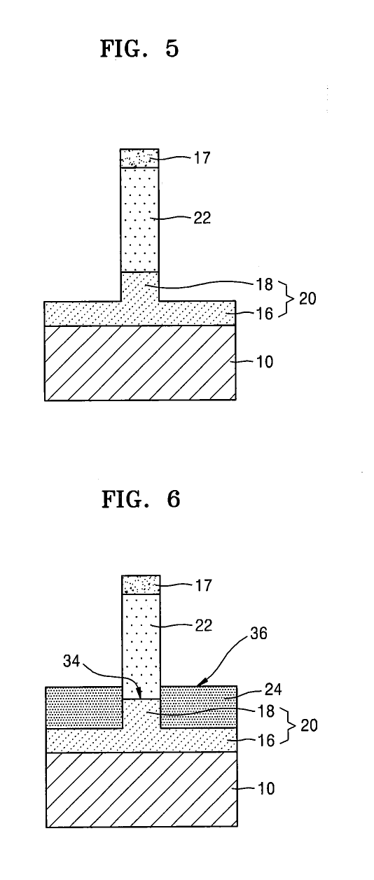

Referring to FIG. 5, the second semiconductor layer 14 of FIG. 4 may be patterned to form the semiconductor fin 22. For example, a mask layer 17 may be formed on the second semiconductor layer 14. The mask layer 17 may be, for example, a silicon nitride (SiN) layer. The mask layer 17 may be used as an etching mask to etch the second semiconductor layer 14 to form the semiconductor fin 22. When etching the second semiconductor layer 14, a portion of the first semiconductor layer 12 may also be etched so as to form a protruding pattern 18 under the semiconductor fin 22. Accordingly, a patterned first semiconductor layer 20 including a planar pattern 16 formed on the silicon layer 10 and the protruding pattern 18 protruding from the planar pattern 16 under the semiconductor fin 22 may be formed.

Referring to FIG. 6, an isolation insulation layer 24 may be formed at two lower sidewalls of the semiconductor fin 22. The isolation insulation layer 24 may be formed on opposing sides of a lower portion of the semiconductor fin 22. The isolation insulation layer 24 may be an insulation structure that electrically insulates the semiconductor fin 22 from other elements. The isolation insulation layer 24 may be formed on the planar pattern 16 and on two sides (i.e., opposing sides) of the protruding pattern 18. The isolation insulation layer 24 may be an oxide layer that is formed by depositing an insulation material. For example, the isolation insulation layer 24 may be a silicon oxide layer formed by depositing a silicon oxide.

As illustrated in FIG. 6, an upper surface 36 of the isolation insulation layer 24 may be higher than a lower surface 34 of the semiconductor fin 22. In some embodiments, the upper surface 36 of the isolation insulation layer 24 may be at the same height as the lower surface 34 of the semiconductor fin 22 as illustrated in FIG. 2.

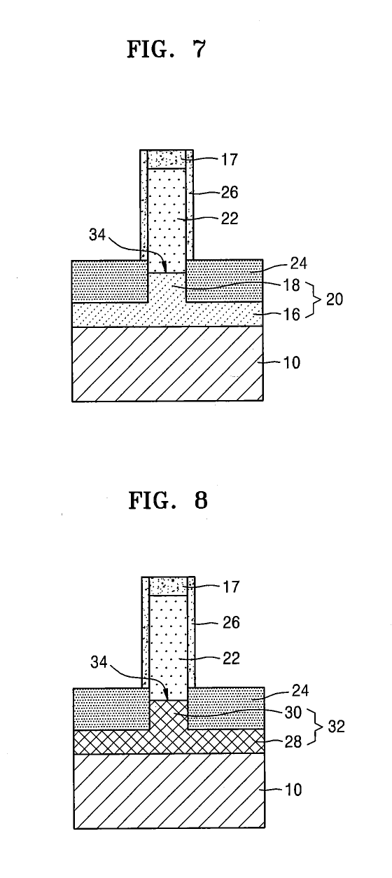

Referring to FIGS. 7 and 8, a sidewall spacer 26 may be formed on exposed portions of the sidewalls of the semiconductor fin 22 and the mask layer 17 as illustrated in FIG. 7. The sidewall spacer 26 may protect the semiconductor fin 22 during an oxidization process which will be described later. For example, the sidewall spacer 26 may be formed of the same material as the mask layer 17. The sidewall spacer 26 may be formed of, for example, a silicon nitride (SiN) layer. It will be understood that the sidewall spacer 26 may be a protective layer that is formed on exposed surfaces of the semiconductor fin 22 such that the exposed surfaces of the semiconductor fin 22 are not oxidized during the oxidization process.

As illustrated in FIG. 8, while the semiconductor fin 22 is being protected, the patterned first semiconductor layer 20 may be oxidized to form a bottom insulation layer 32 that is disposed under the isolation insulation layer 24. The bottom insulation layer 32 may be an insulation structure that electrically insulates the semiconductor fin 22 from other elements. The bottom insulation layer 32 may be an oxide layer that is formed by oxidizing a Group IV semiconductor material including germanium. For example, the bottom insulation layer 32 may be a silicon germanium oxide (SiGeO) layer.

In some embodiments, the bottom insulation layer 32 and the isolation insulation layer 24 may be different materials. A density of the bottom insulation layer 32 which is formed by oxidizing the patterned first semiconductor layer 20 may be higher than a density of the isolation insulation layer 24 which is formed by depositing an insulation material. When the density of the bottom insulation layer 32 is higher than that of the isolation insulation layer 24, electrical insulation characteristics between the semiconductor fin 22 and the silicon layer 10 may be further improved.

The mask layer 17 and the sidewall spacer 26 may be removed to form the fin structure 100a as illustrated in FIG. 1. Also, when the upper surface 36 of the isolation insulation layer 24 and the lower surface 34 of the semiconductor fin 22 are disposed at the same height, the fin structure 100b as illustrated in FIG. 2 may be formed.

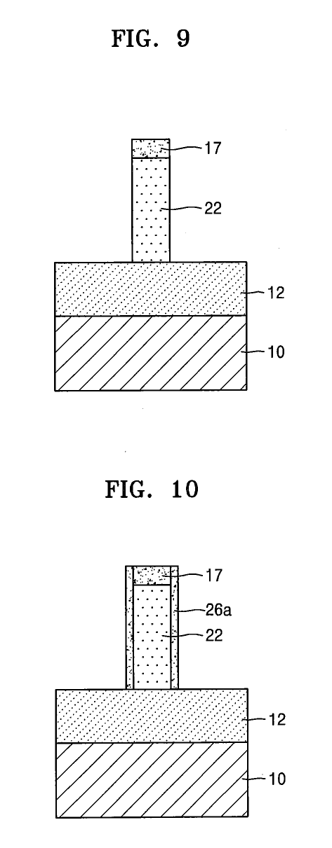

FIGS. 9 through 13 are schematic cross-sectional views illustrating a method of manufacturing a fin structure according to some embodiments of the present inventive concepts.

In detail, the method illustrated in FIGS. 9 through 13 may be used to manufacture the fin structures 100b and 100c of FIGS. 2 and 3. As described above with reference to FIG. 4, the first semiconductor layer 12 and the second semiconductor layer 14 may be formed on the silicon layer 10.

Referring to FIG. 9, the second semiconductor layer 14 may be patterned to form a semiconductor fin 22. For example, the mask layer 17 may be formed on the second semiconductor layer 14 of FIG. 4. Next, the mask layer 17 may be used as an etching mask to etch the second semiconductor layer 14 and to form the semiconductor fin 22.

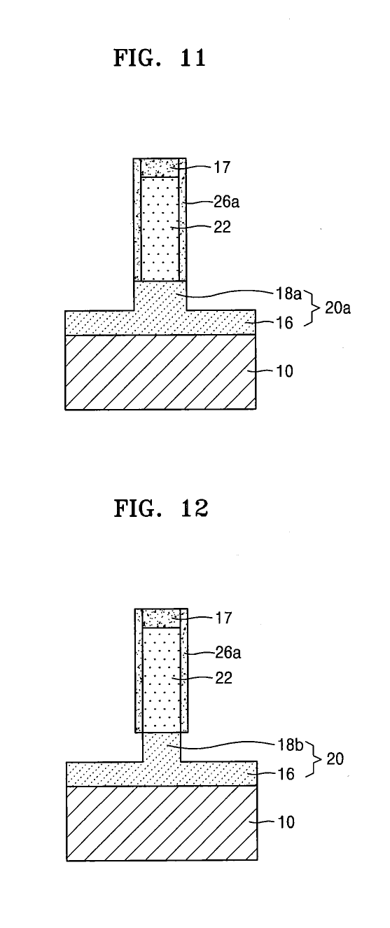

Referring to FIGS. 10 and 11, a sidewall spacer 26a may be formed on opposed sidewalls of the semiconductor fin 22 and the mask layer 17 as illustrated in FIG. 10. The sidewall spacer 26a may protect the semiconductor fin 22 during an oxidization process which will be described later. The sidewall spacer 26a may be the same material as the mask layer 17. The sidewall spacer 26a may be a silicon nitride (SiN) layer.

Referring to FIG. 11, the mask layer 17 and the sidewall spacer 26a may be used as an etching mask to etch a portion of the first semiconductor layer 12 and to form a protruding pattern 18a that is disposed under the semiconductor fin 22 and the sidewall spacer 26a. Accordingly, a patterned first semiconductor layer 20a including a planar pattern 16 formed on the silicon layer 10 and the protruding pattern 18a protruding from the planar pattern 16 that is disposed under the semiconductor fin 22 and the sidewall spacer 26a may be formed.

Referring to FIG. 12, the protruding pattern 18a formed under the sidewall spacer 26a may be etched to form a recessed protruding pattern 18b. Accordingly, a patterned first semiconductor layer 20 including the recessed protruding pattern 18b and the planar pattern 16 may be formed.

Referring to FIG. 13, while the semiconductor fin 22 is being protected, the patterned first semiconductor layer 20 including the recessed protruding pattern 18b may be oxidized to form a bottom insulation layer 32. Further, an isolation insulation layer 24 may be formed at two lower sides of the semiconductor fin 22. The bottom insulation layer 32 and the isolation insulation layer 24 may together comprise an insulation structure that electrically insulates the semiconductor fin 22 from other elements. As illustrated in FIG. 13, the upper surface 36a of the isolation insulation layer 24 may be at the same height as the lower surface 34 of the semiconductor fin 22. The bottom insulation layer 32 and the isolation insulation layer 24 are described above with reference to FIGS. 4 through 8, and thus description thereof will be omitted.

Further, the mask layer 17 and the sidewall spacer 26a may be removed to form the fin structure 100b of FIG. 2. In other embodiments, after removing the mask layer 17 and the sidewall spacer 26a, the isolation insulation layer 24 may be further etched so that an upper surface 36a of the isolation insulation layer 24 may be lower than the lower surface 34 of the semiconductor fin 22, as in the fin structure 100c of FIG. 3.

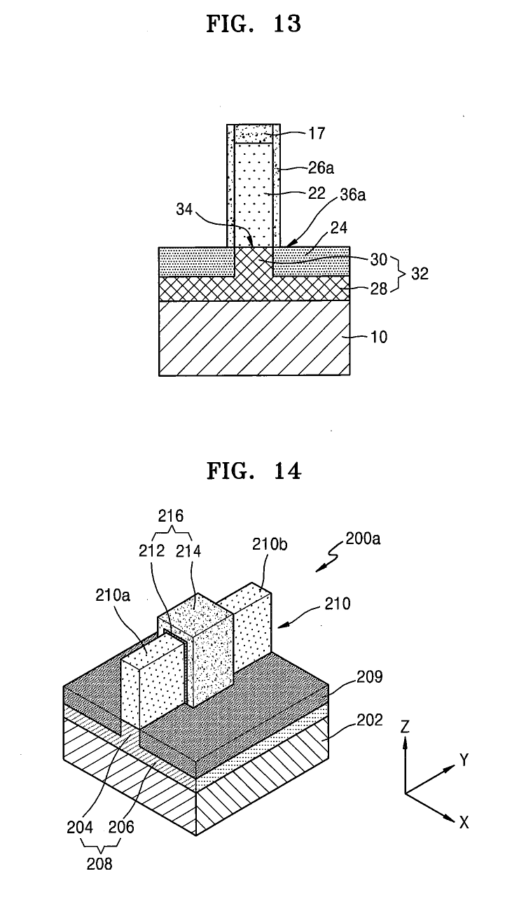

FIG. 14 is a schematic perspective view of a fin transistor 200a including a single semiconductor fin according to some embodiments of the present inventive concepts.

In detail, the fin transistor 200a may include a semiconductor fin 210 disposed on a silicon layer 202, a gate structure 216 disposed on the semiconductor fin 210, and insulation structures 208 and 209 disposed under the gate structure 216 and the semiconductor fin 210. The fin transistor 200a may be a fin field effect transistor or a fin metal oxide silicon (MOS) transistor. The silicon layer 202 may be a bulk silicon substrate. The insulation structures 208 and 209 may be formed on the bulk silicon substrate.

The semiconductor fin 210 may be formed of a Group IV semiconductor material that includes germanium (Ge). The semiconductor fin 210 may be a silicon germanium (SiGe) layer, a silicon germanium carbon (SiGeC) layer, or a germanium (Ge) layer. The semiconductor fin 210 may be formed of the same material as the semiconductor fin 22 described above with reference to FIGS. 1 through 3. A source area 210a and a drain area 210b may be formed in the semiconductor fin 210 on opposed sides of the gate structure 216.

The gate structure 216 may include a gate insulation layer 212 and a gate electrode layer 214. The gate insulation layer 212 may be formed of a silicon oxide layer, a silicon nitride layer, a silicon oxynitride layer, a high-k dielectric layer or a combination thereof. The gate electrode layer 214 may be formed of a polysilicon layer doped with an impurity, a metal layer, a metal nitride layer, and/or a metal silicide layer. The insulation structures 208 and 209 may include an isolation insulation layer 209 that is formed at two lower sides of the semiconductor fin 210 and a bottom insulation layer 208 disposed under the semiconductor fin 210 and the isolation insulation layer 209.

The bottom insulation layer 208 may include a planar portion 206 formed on the silicon layer 202 and a protruding portion 204 protruding from the planar portion 206 under the semiconductor fin 210. The isolation insulation layer 209 may be formed on opposed sides of the protruding portion 204 of the bottom insulation layer 208.

The bottom insulation layer 208 may be an oxide layer that is formed of a Group IV semiconductor material including germanium. The isolation insulation layer 209 may be a deposition layer formed by depositing an insulation material. Accordingly, the bottom insulation layer 208 and the isolation insulation layer 209 may be formed of different materials. A density of the bottom insulation layer 208 may be higher than a density of the isolation insulation layer 209. The bottom insulation layer 208 may be formed of the same material as the bottom insulation layer 32 that is described above with reference to FIGS. 1-3, and the isolation insulation layer 209 may be formed of the same material as the isolation insulation layers 24, 24a, and 24b described above with reference to FIGS. 1 through 3.

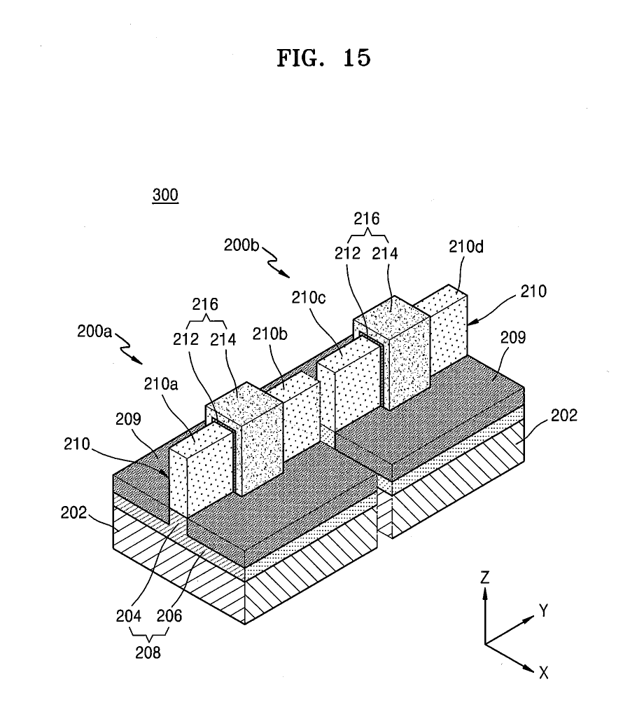

FIG. 15 is a schematic perspective view of a fin transistor 300 that includes a single semiconductor fin according to some embodiments of the present inventive concepts.

In detail, the fin transistor 300 of FIG. 15 may be the same as the fin transistor 200a of FIG. 14 except that the fin transistor 300 of FIG. 15 includes two fin transistors 200a and 200b.

The fin transistor 300 may include a first fin transistor 200a and a second fin transistor 200b. The fin transistor 200a is described above with reference to FIG. 14 and thus description thereof will be omitted. The fin transistor 200b may be the same as the fin transistor 200a except for conductivity types of a source area and a drain area.

For example, a source area 210a and a drain area 210b of the fin transistor 200a may be p-type impurity areas. The fin transistor 200a thus may be a p-type MOS transistor. The source area 210a and the drain area 210b of the fin transistor 200a may be n-type impurity areas. The fin transistor 200a may thus be an n-type MOS transistor. The fin transistor 300 may include both a p-type MOS transistor and an n-type MOS transistor.

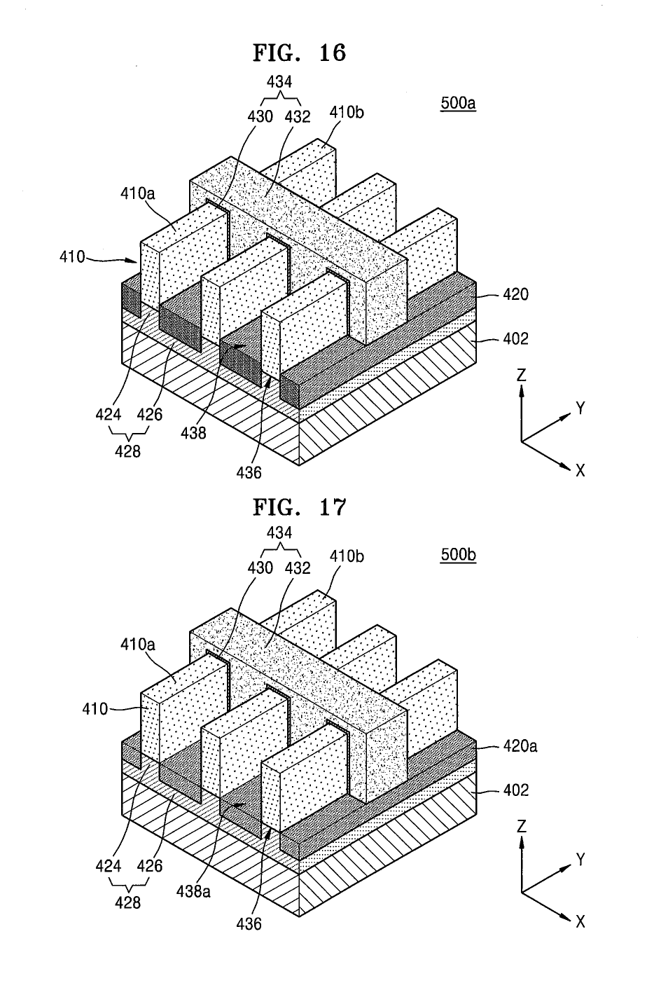

FIG. 16 is a schematic perspective view of a fin transistor 500a including a plurality of semiconductor fins 410 according to some embodiments of the present inventive concepts.

In detail, the fin transistor 500a of FIG. 16 may include semiconductor fins 410, a gate structure 434, source and drain areas 410a and 410b, and insulation structures 428 and 438.

The semiconductor fins 410 may be disposed on a silicon layer 402. The silicon layer 402 may be a bulk silicon substrate. The semiconductor fins 410 may protrude from the silicon layer 402 in an upward direction (Z direction), may be spaced apart from one another in a first direction (X direction) and may extend in a second direction (Y direction) which is substantially perpendicular to the first direction. The semiconductor fins 410 may be formed of a Group IV semiconductor material that includes germanium (Ge). The semiconductor fins 410 may be a silicon germanium (SiGe) layer, a silicon germanium carbon (SiGeC) layer, or a germanium (Ge) layer. The semiconductor fins 410 may be formed of the same material as the semiconductor fin 22 described above with reference to FIGS. 1 through 3.

A gate structure 434 formed on the plurality of semiconductor fins 410. The gate structure 434 extends in the first direction to surround the semiconductor fins 410. The gate structure 434 may include a gate insulation layer 430 and a gate electrode layer 432.

The source areas 410a and the drain areas 410b may be formed in the semiconductor fins 410 on opposed sides of the gate structure 434. Each of the source and drain areas 410a and 410b may be an n-type impurity area or a p-type impurity area.

The insulation structures 420 and 428 may be formed under the gate structure 434 and the semiconductor fins 410. The insulation structures 420 and 428 may include an isolation insulation layer 420 that is formed on opposed sides of the semiconductor fins 410 and between the semiconductor fins 410 and a bottom insulation layer 428 that is disposed under the semiconductor fins 410 and the isolation insulation layer 420 and on the silicon layer 402.

The bottom insulation layer 428 may include a planar portion 426 that is formed on the silicon layer 402 and protruding portions 424 that protrude from the planar portion 426 under the semiconductor fins 410. The isolation insulation layer 420 may be formed on opposed sides of each protruding portion 424 on the bottom insulation layer 428. An upper surface 438 of the isolation insulation layer 420 may be higher than a lower surface 436 of the semiconductor fins 410 as illustrated in FIG. 16. Accordingly, a leakage current under the semiconductor fins 410 may be reduced.

The bottom insulation layer 428 may be an oxide layer formed by oxidizing a Group IV semiconductor material including germanium. The isolation insulation layer 420 may be a deposition layer that is formed by depositing an insulation material. The bottom insulation layer 428 and the isolation insulation layer 420 may be formed of different materials. A density of the bottom insulation layer 428 may be higher than a density of the isolation insulation layer 420. The bottom insulation layer 428 may be formed of the same material as the bottom insulation layer 32, and the isolation insulation layer 420 may be formed of the same material as the isolation insulation layers 24, 24a, and 24b described above with reference to FIGS. 1 through 3.

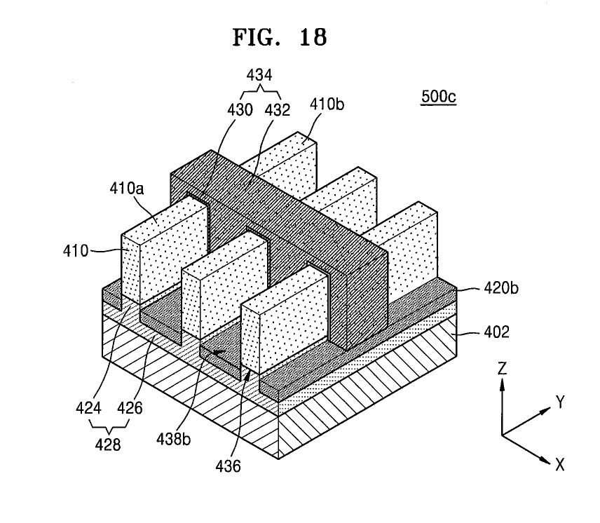

FIGS. 17 and 18 are schematic cross-sectional views of fin transistors 500b and 500c that include a plurality of semiconductor fins according to some embodiments of the present inventive concepts.

In detail, the fin transistors 500b and 500c of FIGS. 17 and 18 are similar to the fin transistor 500a of FIG. 16 except that the fin transistors 500b and 500c include isolation insulation layers 420a and 420b in place of the isolation insulation layer 420 of the fin transistor 500a. In regard to the fin transistors 500b and 500c of FIGS. 17 and 18, description repeated with respect to the fin transistor 500a will be omitted.

Referring to FIG. 17, an upper surface 438a of the isolation insulation layer 420a may be at the same height as the lower surfaces 436 of the semiconductor fins 410. The fin transistor 500b of FIG. 17 may have a height of the semiconductor fins 410 that may be greater than that of the fin transistor 500a of FIG. 16.

Referring to FIG. 18, in the fin transistor 500c, an upper surface 438b of the isolation insulation layer 420b may be lower than lower surfaces 436 of the semiconductor fins 410. The semiconductor fins 410 of the fin transistor 500c may not overlap with the isolation insulation layer 420b which has a relatively low density. Accordingly, the fin transistor 500c of FIG. 18 may further improve insulation characteristics between the semiconductor fins 410 and the silicon layer 402.

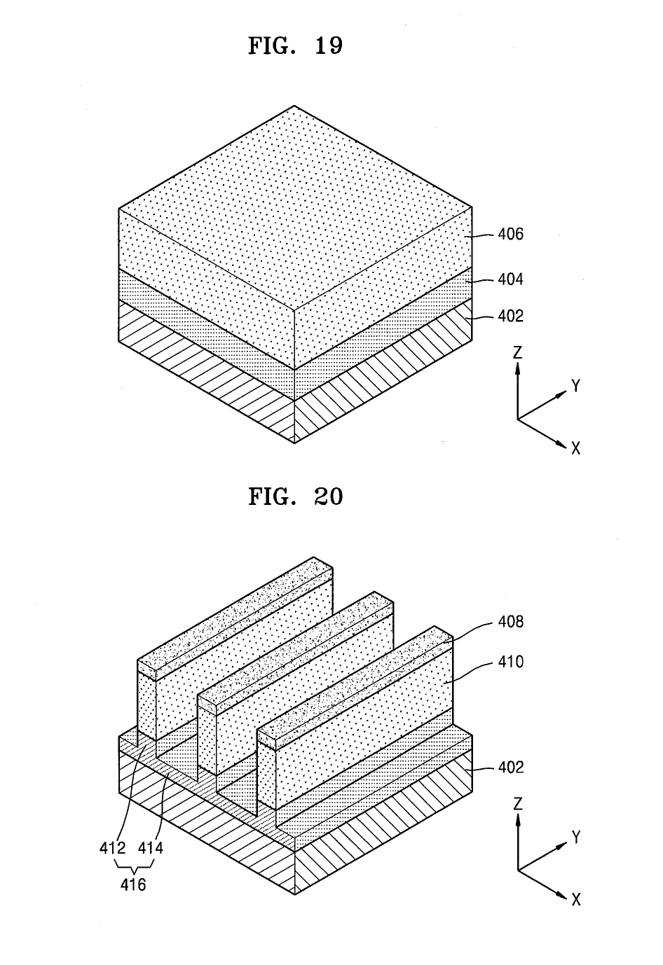

FIGS. 19 through 24 are schematic cross-sectional views illustrating a method of manufacturing a fin transistor including a plurality of semiconductor fins according to some embodiments of the present inventive concepts.

In detail, the method of manufacturing a fin structure illustrated in FIGS. 19 through 24 may be used to manufacture the fin structures 500a and 500b of FIGS. 16 and 17.

Referring to FIG. 19, a first semiconductor layer 404 formed of a Group IV semiconductor including germanium (Ge) may be formed on the silicon layer 402. The silicon layer 402 may be a bulk silicon substrate. The first semiconductor layer 404 may be formed using a Group IV material source including germanium (Ge) and using an epitaxial deposition method.

A second semiconductor layer 406 formed of a Group IV semiconductor material including Ge may be formed on the first semiconductor layer 404. The second semiconductor layer 406 may be formed using a Group IV material source including Ge and using an epitaxial deposition method. The first semiconductor layer 404 and the second semiconductor layer 406 may be a silicon germanium (SiGe) layer, a silicon germanium carbon (SiGeC) layer, or a germanium (Ge) layer. The first semiconductor layer 404 and the second semiconductor layer 406 may be formed of the same materials as the first semiconductor layer 12 and the second semiconductor layer 14 of FIG. 4.

Referring to FIG. 20, the second semiconductor layer 406 may be patterned to form a plurality of semiconductor fins 410. A mask layer 408 may be formed on the second semiconductor layer 406. The mask layer 408 may be formed of silicon nitride (SiN).

Next, the mask layer 408 may be used as an etching mask to etch the second semiconductor layer 406 to form the semiconductor fins 410. As described above, the semiconductor fins 410 may protrude from the silicon layer 402 in an upward direction (Z direction), may be spaced apart from one another in a first direction (X direction) and may extend in a second direction (Y direction) which is substantially perpendicular to the first direction.

When etching the second semiconductor layer 406, a portion of the first semiconductor layer 404 may also be etched so as to form a protruding pattern 412 under each of the semiconductor fins 410. Accordingly, a patterned first semiconductor layer 416 including a planar pattern 414 formed on the silicon layer 402 and protruding patterns 412 protruding from the planar pattern 414 under the semiconductor fins 410 may be formed.

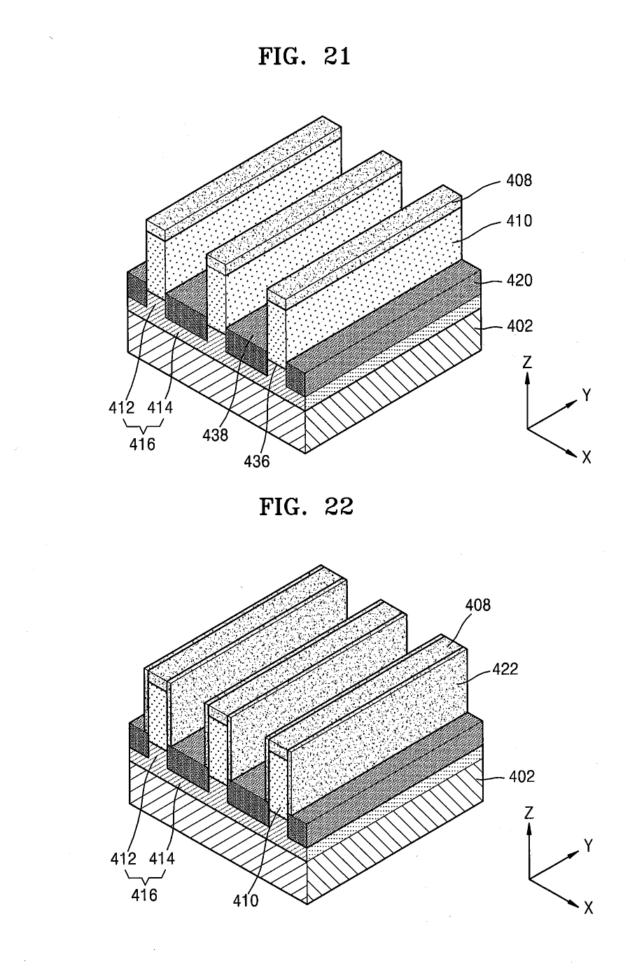

Referring to FIG. 21, an isolation insulation layer 420 may be formed at opposed lower sides of the semiconductor fins 410. The isolation insulation layer 420 may be an insulation structure that electrically insulates the semiconductor fins 410 from other elements. The isolation insulation layer 420 may be formed on the planar pattern 414 and on opposed sides of the protruding pattern 412. The isolation insulation layer 420 may be an oxide layer that is formed by depositing an insulation material. For example, the isolation insulation layer 420 may be a silicon oxide layer formed by depositing a silicon oxide.

As illustrated in FIG. 21, an upper surface 438 of the isolation insulation layer 420 may be higher than lower surfaces 436 of the semiconductor fins 410. In some embodiments, the upper surface 438a of the isolation insulation layer 420 may be at the same height as the lower surface 436 of the semiconductor fins 410 as illustrated in FIG. 17.

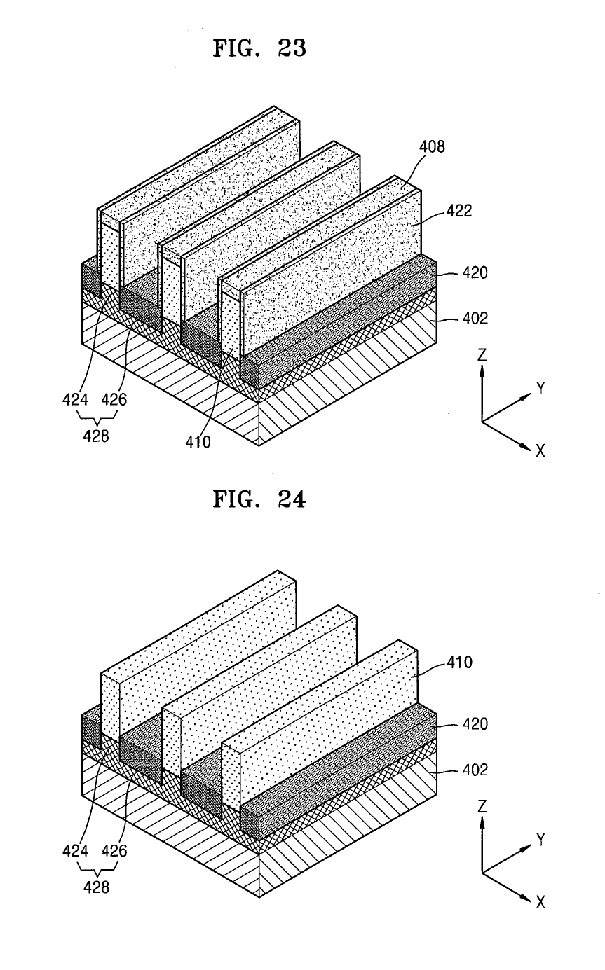

Referring to FIGS. 22 and 23, a sidewall spacer 422 may be formed on sides of the semiconductor fins 410 and the mask layer 408 as illustrated in FIG. 22. The sidewall spacer 422 may protect the semiconductor fins 410 during an oxidization process which will be described later. The sidewall spacer 422 may be formed of the same material as the mask layer 408. The sidewall spacer 422 may be, for example, a silicon nitride (SiN) layer.

As illustrated in FIG. 23, while the semiconductor fins 410 is being protected, the patterned first semiconductor layer 416 may be oxidized to form a bottom insulation layer 428 under the isolation insulation layer 420. The bottom insulation layer 428 may be an insulation structure that electrically insulates the semiconductor fins 410 from other elements. The bottom insulation layer 428 may be an oxide layer that is formed by oxidizing a Group IV semiconductor material including germanium. For example, the bottom insulation layer 428 may be a silicon germanium oxide (SiGeO) layer.

Accordingly, the bottom insulation layer 428 and the isolation insulation layer 420 may be different materials. Also, a density of the bottom insulation layer 428 which is formed by oxidizing the patterned first semiconductor layer 416 may be higher than a density of the isolation insulation layer 420 which is formed by depositing an insulation material. When the density of the bottom insulation layer 428 is higher than that of the isolation insulation layer 420, electrical insulation characteristics between the semiconductor fins 410 and the silicon layer 402 may be further improved.

Referring to FIG. 24, the mask layer 408 and the sidewall spacer 422 may be removed to expose the semiconductor fins 410. As illustrated in FIG. 16, a gate structure 434 is formed on the semiconductor fins 410. The gate structure 434 extends in the first direction to surround the semiconductor fins 410. The gate structure 434 may include a gate insulation layer 430 and a gate electrode layer 432.

Referring again to FIG. 16, n-type impurities or a p-type impurities may be implanted into the semiconductor fins 410 in both sides of the gate structure 434 to form source areas 410a and drain areas 410b. In some embodiments, the upper surface 438 of the isolation insulation layer 420 and the lower surface 436 of the semiconductor fins 410 may be disposed at the same height as illustrated in FIG. 17.

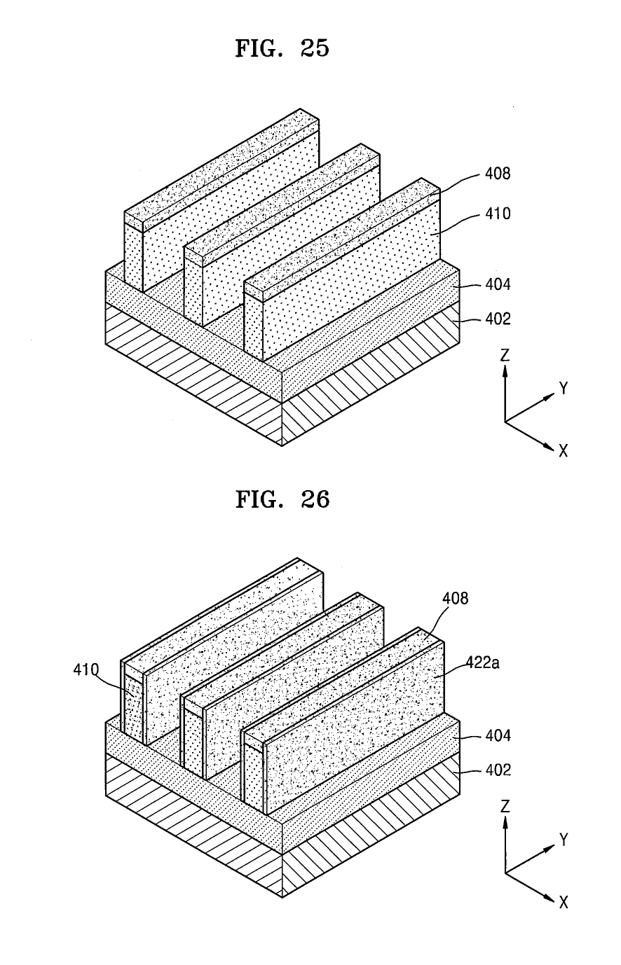

FIGS. 25 through 31 are schematic cross-sectional views illustrating a method of manufacturing a fin transistor including a plurality of semiconductor fins according to some embodiments of the present inventive concepts.

The method illustrated in FIGS. 25 through 31 may be used to manufacture the fin structures 500b and 500c of FIGS. 17 and 18. Referring again to FIG. 19, the first semiconductor layer 404 and the second semiconductor layer 406 are formed on the silicon layer 402.

Referring to FIG. 25, the second semiconductor layer 406 may be patterned to form semiconductor fins 410. For example, a mask layer 408 may be formed on the second semiconductor layer 406. Next, the mask layer 408 may be used as an etching mask to etch the second semiconductor layer 406 and to form the semiconductor fins 410.

Referring to FIG. 26, a sidewall spacer 422a may be formed on sides of the semiconductor fins 410 and the mask layer 408 as illustrated in FIG. 26. The sidewall spacer 422a may protect the semiconductor fins 410 in an oxidization process which will be described later. The sidewall spacer 422a may be the same material as the mask layer 408. The sidewall spacer 422a may be formed of a silicon nitride (SiN) layer.

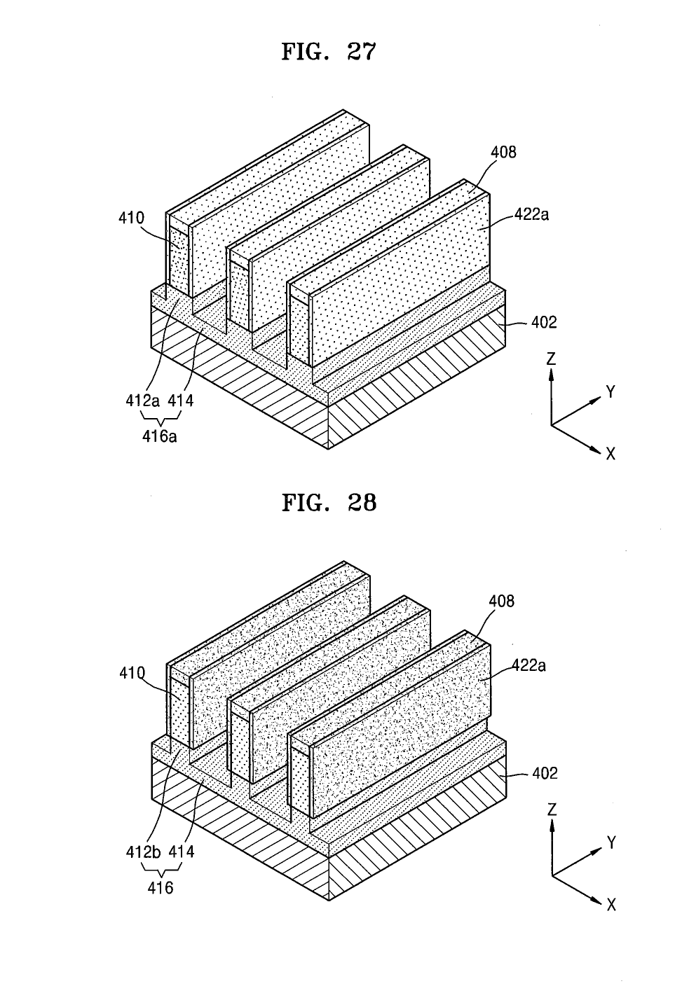

Referring to FIG. 27, the mask layer 408 and the sidewall spacer 422a may be used as an etching mask to etch a portion of the first semiconductor layer 404 and to form protruding patterns 412a under the semiconductor fins 410 and the sidewall spacer 422a. Accordingly, a patterned first semiconductor layer 416a including a planar pattern 414 formed on the silicon layer 402 and the protruding patterns 412a that protrude from the planar pattern 414 under the semiconductor fins 410 and the sidewall spacer 422a may be formed.

Referring to FIG. 28, the protruding patterns 412a formed under the sidewall spacer 422a may be etched to form recessed protruding patterns 412b. Accordingly, a patterned first semiconductor layer 416 including the recessed protruding patterns 412b and the planar pattern 414 may be formed.

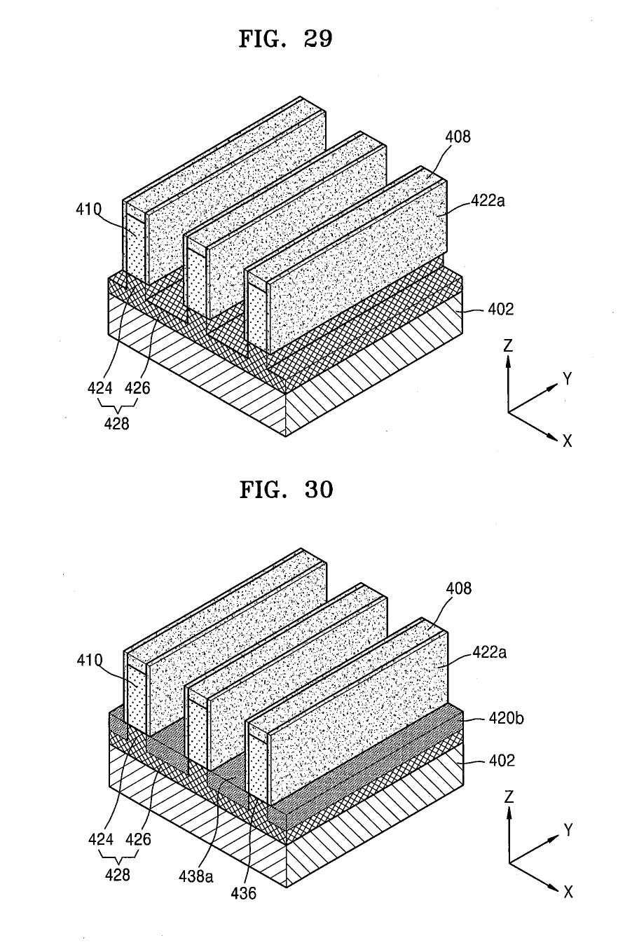

Referring to FIG. 29, while the semiconductor fins 410 are protected, the patterned first semiconductor layer 416 that includes the recessed protruding patterns 412b may be oxidized to form a bottom insulation layer 428. The bottom insulation layer 428 may include a planar portion 426 formed on the silicon layer 402 and protruding portions 424 that protrude from the planar portion 426 under the semiconductor fins 410.

Referring to FIG. 30, an isolation insulation layer 420b may be formed at opposed lower sides of the semiconductor fins 410. The bottom insulation layer 428 and the isolation insulation layer 420b may be insulation structures that electrically insulate the semiconductor fins 410 from other elements. As illustrated in FIG. 30, an upper surface 438a of the isolation insulation layer 420 may be at the same height as the lower surfaces 436 of the semiconductor fins 410. The bottom insulation layer 428 and the isolation insulation layer 420 are described above with reference to FIGS. 19 through 24 and thus description thereof will be omitted.

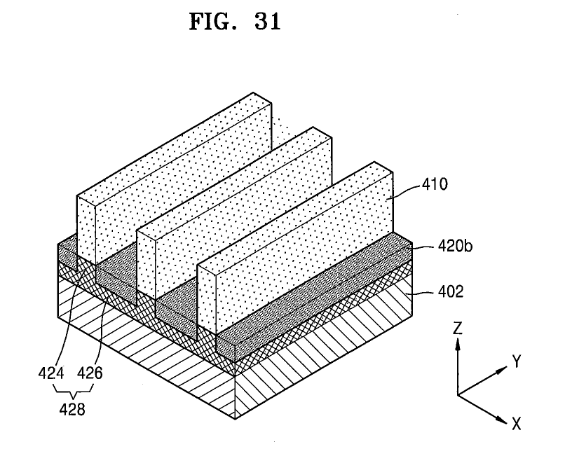

Referring to FIG. 31, the mask layer 408 and the sidewall spacer 422a may be removed to expose the semiconductor fins 410. In some embodiments, the mask layer 408 and the sidewall spacer 422a may be removed and the isolation insulation layer 420 may be further etched such that the upper surface 438b of the isolation insulation layer 420 may be lower than the lower surface 436 of the semiconductor fins 410 as illustrated in FIG. 18.

Referring again to FIGS. 17 and 18, a gate structure 434 is formed on the semiconductor fins 410. The gate structure 434 extends in the first direction to surround the semiconductor fins 410. The gate structure 434 may include a gate insulation layer 430 and a gate electrode layer 432.

Further, n-type impurities or p-type impurities may be implanted into the semiconductor fins 410 in both sides of the gate structure 434 to form the source areas 410a and the drain areas 410b that are illustrated in FIGS. 17 and 18.

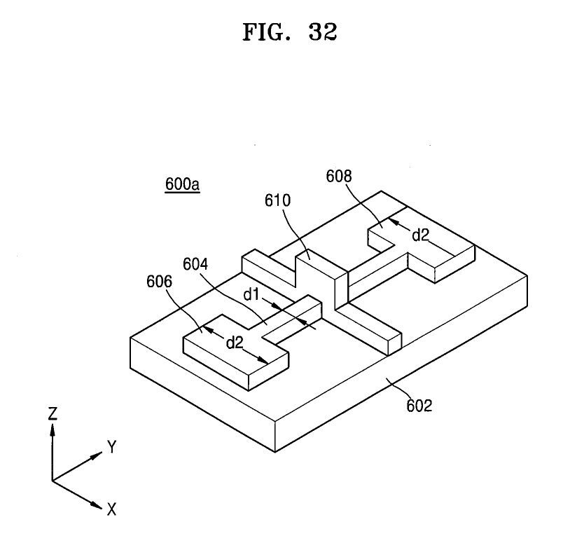

FIG. 32 is a perspective view of a fin transistor 600a including semiconductor fins according to some embodiments of the present inventive concepts.

In detail, the fin transistor 600a includes semiconductor fins 604, 606, and 608 formed on an insulation structure 602. The insulation structure 602 may correspond to the insulation structures 208 and 209 of FIG. 14. The semiconductor fins 604, 606, and 608 may correspond to the semiconductor fin 210 of FIG. 14. The gate structure 610 may correspond to the gate structure 216 of FIG. 14. A silicon layer under the insulation structure 602 is not illustrated in FIG. 32 for convenience of description.

The semiconductor fins 604, 606, and 608 may extend in the second direction (Y direction), and the gate structure 610 may extend in the first direction (X direction) that is substantially perpendicular to the second direction. As illustrated in FIG. 32, the semiconductor fins 604, 606, and 608 may have different widths in the first direction (i.e., d1 and d2 are different). The semiconductor fins 604, 606, and 608 formed in both sides of the gate structure 610 may be implanted with n-type or p-type impurities to form a source area and a drain area.

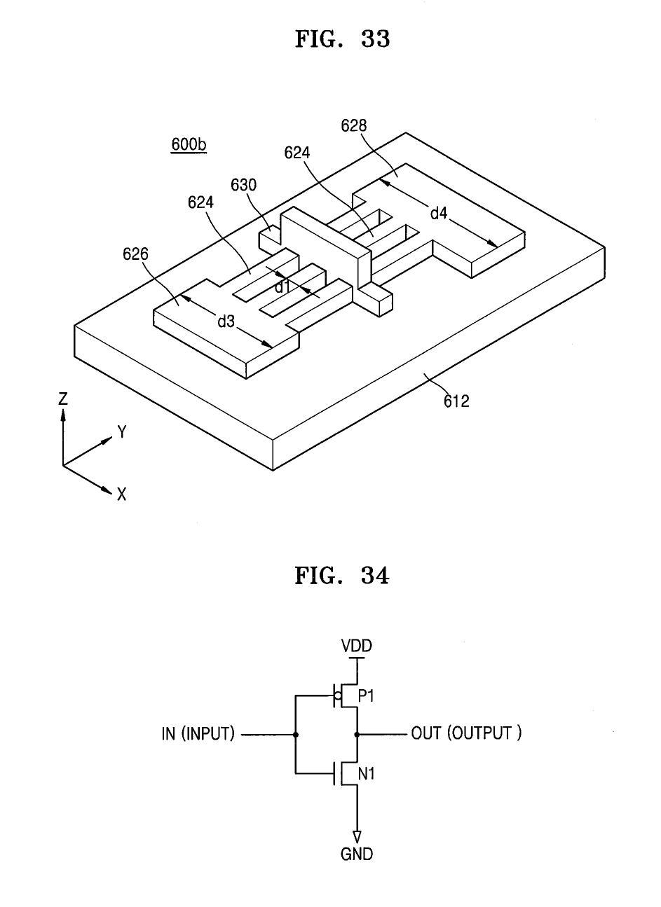

FIG. 33 is a perspective view of a fin transistor including semiconductor fins according to some embodiments of the present inventive concepts.

In detail, the fin transistor 600b may include a plurality of semiconductor fins 624, 626, and 628 formed on an insulation structure 612. The insulation structure 612 may correspond to the insulation structures 428, 420, 420a, and 420b of FIGS. 16 through 18. The semiconductor fins 624, 626, and 628 may correspond to the semiconductor fins 410 of FIGS. 16 through 18. A gate structure 630 may be formed on the semiconductor fins 624 and the insulation structure 612. The gate structure 630 may correspond to the gate structure 434 of FIGS. 16 through 18. A silicon layer under the insulation structure 612 is not illustrated in FIG. 33 for convenience of description.

The semiconductor fins 624, 626, and 628 may extend in the second direction (Y direction), and the gate structure 630 may extend in the first direction (X direction) that is substantially perpendicular to the second direction. As illustrated in FIG. 33, the semiconductor fins 624, 626, and 628 may have different widths in the first direction (i.e., d1, d3 and d4 are different). As illustrated in FIG. 33, three semiconductor fins 624 may be merged into a unitary semiconductor fin 628 having a width d4 in the first direction. The semiconductor fins 624, 626, and 628 formed in both sides of the gate structure 630 may be implanted with n-type or p-type impurities to form a source area and a drain area.

FIG. 34 is a circuit diagram of an inverter including a fin transistor according to some embodiments of the present inventive concepts.

In detail, the inverter may be a complementary metal oxide semiconductor (CMOS) transistor including a PMOS transistor P1 and an NMOS transistor N1. The PMOS transistor P1 and the NMOS transistor N1 may include a fin transistor according to some embodiments of the present inventive concepts described above.

The PMOS transistor P1 and the NMOS transistor N1 may be serially connected between a driving voltage VDD and a ground voltage GND, and an input signal IN is a common input to gates of the PMOS transistor P1 and the NMOS transistor N1. Also, an output signal OUT is a common output of drains of the PMOS transistor P1 and the NMOS transistor N1.

The driving voltage VDD is applied to a source of the PMOS transistor P1, and a ground voltage GND is applied to a source of the NMOS transistor N1. The CMOS inverter inverts the input signal IN. In other words, when a logic level ‘1’ is input as an input signal of the inverter, a logic level ‘0’ is output as an output signal. When a logic level ‘0’ is input as an input signal of the inverter, a logic level ‘1’ is output as an output signal.

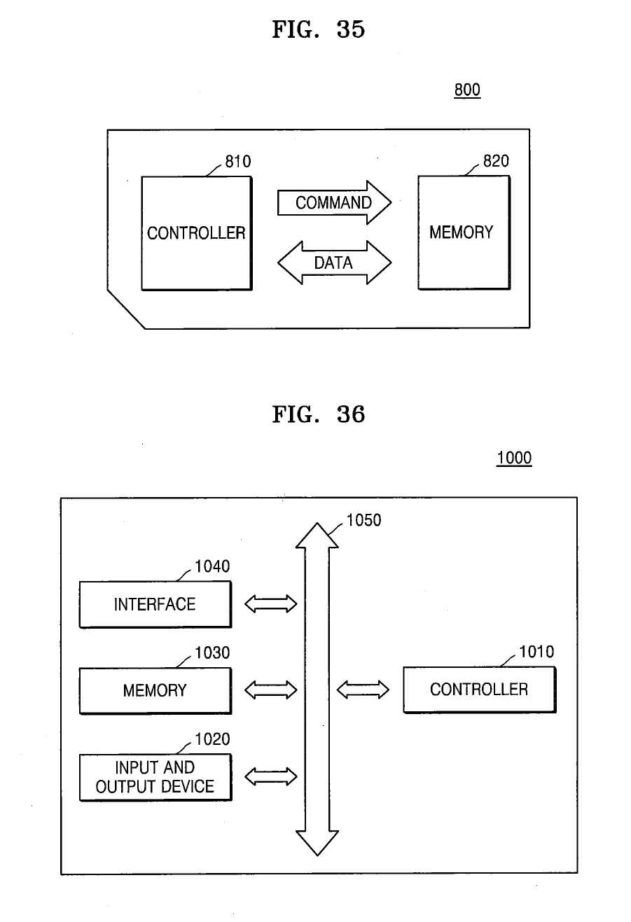

FIG. 35 is a schematic view illustrating a card 800 including a fin transistor according to some embodiments of the present inventive concepts.

In detail, in the card 800, a controller 810 and a memory 820 may exchange an electrical signal with each other. For example, when the controller 810 provides a command, the memory 820 may transmit data. The memory 820 or the controller 810 may include a fin transistor according to some embodiments of the present inventive concepts. Examples of the card 800 may include a memory stick card, a smart media card (SM) card, a secure digital (SD) card, a mini secure digital (mini SD) card, and a multi media card (MMC).

FIG. 36 is a schematic view illustrating an electronic system 1000 including a fin transistor according to some embodiments of the present inventive concepts.

In detail, the electronic system 1000 may include a controller 1010, an input and output device 1020, a memory 1030, and an interface 1040. The electronic system 1000 may be a mobile system or a system that transmits or receives information. Examples of the mobile system may include a personal digital assistant (PDA), a portable computer, a web tablet, a wireless phone, a mobile phone, a digital music player or a memory card.

The controller 1010 may execute a program and control a system 1100. The controller 1010 may include a fin transistor according to some embodiments of the present inventive concepts. The controller 1010 may be, for example, a microprocessor, a digital signal processor, a microcontroller or a similar device thereto.

The input and output device 1020 may be used to input or output data of the electronic system 1000. The electronic system 1000 may be connected to an external device such as a personal computer or a network by using the input and output device 1020 and may exchange data with the external device. The input and output device 1020 may be, for example, a keypad, a keyboard, or a display.

The memory 1030 may store codes and/or data to operate the controller 1110 and/or may store data processed by the controller 1110. The memory 1030 may include a fin transistor according to some embodiments of the present inventive concepts. The interface 1040 may be a data transmission path between the electronic system 1000 and another external device. The controller 1010, the input and output device 1020, the memory 1030, and the interface 1040 may communicate with one another via a bus 1050.

For example, the electronic system 1000 may be used in a mobile phone, a MP3 player, a navigation device, a portable multimedia player (PMP), a solid state disk (SSD) or household appliances.

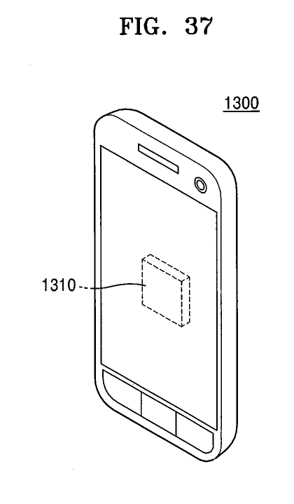

FIG. 37 is a schematic perspective view of an electronic device including a fin transistor according to some embodiments of the present inventive concepts.

In detail, FIG. 37 illustrates a mobile phone 1300 as an example of the electronic system 1000 of FIG. 36. The mobile phone 1300 may include a system on chip 1310. The system on chip 1310 may include a fin transistor according to some embodiments of the present inventive concepts. The mobile phone 1300 may include the system on chip 1310 on which a main functional block having a high performance may be disposed, and thus, the mobile phone 1300 may have a high performance.

In addition, the system on chip 1310 may have a relatively small surface area and may provide relatively a high performance. Therefore, a size of the mobile phone 1300 may be small and the mobile phone 1300 may provide a high performance.

While the present inventive concepts have been particularly shown and described with reference to embodiments thereof, it will be understood by those of ordinary skill in the art that various changes in form and details may be made therein without departing from the spirit and scope of the present inventive concepts as defined by the appended claims. The embodiments should be considered in a descriptive sense only and not for purposes of limitation. The technical scope of the present inventive concepts should be defined by the technical spirit of the attached claims.

1. A fin structure comprising:
a semiconductor fin on a silicon layer and comprises a Group IV semiconductor material that includes germanium;
a bottom insulation layer under the semiconductor fin, wherein the bottom insulation layer comprises a planar portion on the silicon layer and a protruding portion protruding from the planar portion that is under the semiconductor fin; and
an isolation insulation layer on opposing sides of the protruding portion of the bottom insulation layer.

2. The fin structure of claim 1, wherein the silicon layer comprises a bulk silicon substrate.

3. The fin structure of claim 1, wherein the semiconductor fin comprises a silicon germanium (SiGe) layer, a silicon germanium carbon (SiGeC) layer, or a germanium (Ge) layer.

4. The fin structure of claim 1, wherein the bottom insulation layer comprises an oxide of the Group IV semiconductor material that includes germanium.

5. The fin structure of claim 1, wherein the isolation insulation layer is on opposing sides of the semiconductor fin.

6. The fin structure of claim 1, wherein the isolation insulation layer exposes opposing sides of the semiconductor fin.

7. The fin structure of claim 1, wherein an upper surface of the isolation insulation layer is higher or lower than a lower surface of the semiconductor fin relative to an upper surface of the silicon layer.

8. The fin structure of claim 1, wherein the bottom insulation layer and the isolation insulation layer comprise different materials.

9. The fin structure of claim 1, wherein a density of the bottom insulation layer is higher than a density of the isolation insulation layer.

10. The fin structure of claim 1, wherein the bottom insulation layer comprises a silicon germanium oxide (Si₁₋ₓGeₓO) layer, and the semiconductor fin comprises a silicon germanium (Si_{1-y}Ge_{y}) layer, and wherein 0<x≦1, 0<y≦1, and x≠y.

11. The fin structure of claim 1, wherein the bottom insulation layer comprises a silicon germanium oxide (Si₁₋ₓGeₓO) layer, and the semiconductor fin comprises a silicon germanium (Si_{1-y}Ge_{y}) layer, and wherein 0<x≦1, 0<y≦1, and x≠y.

12. The fin structure of claim 1, wherein the bottom insulation layer comprises a silicon germanium oxide (Si₁₋ₓGeₓO) layer, and the semiconductor fin comprises a silicon germanium (Si_{1-y}Ge_{y}) layer, and wherein 0.1≦x≦0.7, 0.4≦y≦1.0, and x<y.

13.-23. (canceled)

24. A fin transistor comprising:
a semiconductor fin on a silicon layer, the semiconductor fin including source and drain areas and comprising a Group IV semiconductor material that includes germanium;
a gate structure on the semiconductor fin; and
an insulation structure under the gate structure and the semiconductor fin,
wherein the insulation structure comprises an isolation insulation layer that is disposed on opposing sides of a lower portion of the semiconductor fin and a bottom insulation layer that is disposed under the semiconductor fin and the isolation insulation layer.

25. The fin transistor of claim 24, wherein the silicon layer comprises a bulk silicon substrate, and the insulation structure is on the bulk silicon substrate, and wherein the bottom insulation layer comprises an oxide of the Group IV semiconductor material.

26. The fin structure of claim 24, wherein the bottom insulation layer comprises a planar portion on the silicon layer and a protruding portion protruding from the planar portion that is under the semiconductor fin, and the isolation insulation layer is on opposing sides of the protruding portion of the bottom insulation layer.

27. The fin structure of claim 24, wherein the bottom insulation layer and the isolation insulation layer comprise different materials, and a density of the bottom insulation layer is higher than a density of the isolation insulation layer.

28. (canceled)

29. The fin transistor of claim 24, wherein a width of the semiconductor fin varies along a direction that the gate structure extends on both sides of the gate structure.

30. The fin transistor of claim 24, wherein:
the semiconductor fin comprises a first semiconductor fin among a plurality of semiconductor fins that protrude from the silicon layer in an upward direction that is substantially perpendicular to an upper surface of the silicon layer, the plurality of semiconductor fins being spaced apart from one another in a first direction, extending in a second direction that is substantially perpendicular to the first direction and comprising a Group IV semiconductor material that includes germanium;
the gate structure is disposed on the plurality of semiconductor fins and extends in the first direction;
the insulation structure is disposed under the plurality of semiconductor fins; and
the isolation insulation layer is on opposing sides of a lower portion of each of the plurality of semiconductor fins and between adjacent ones of the plurality of semiconductor fins, and the bottom insulation layer is disposed under the plurality of semiconductor fins and the isolation insulation layer and on the silicon layer.

31. The fin structure of claim 30, wherein the bottom insulation layer comprises an oxide layer of the Group IV semiconductor material and comprises a planar portion on the silicon layer and a plurality of protruding portions protruding from the planar portion under the plurality of semiconductor fins, and wherein the isolation insulation layer is on opposing sides of each of the plurality of protruding portions of the bottom insulation layer.

32.-34. (canceled)

35. The fin transistor of claim 30, wherein the plurality of semiconductor fins are merged into a unitary semiconductor fin on both sides of the gate structure.

36.-47. (canceled)
